(19) United States
(12) Patent Application Publication
(10) Pub. No.: US 2006/0234516 A1
(43) Pub. Date: Oct. 19, 2006

(54) Composition for cleaning semiconductor device and method for cleaning semiconductor device using the same

(76) Inventors: Eun Suk Hong, Cheongju-si (KR); Sang Wook Ryu, Cheongju-si (KR); Kang Sup Shin, Icheon-si (KR); Kui Jong Baek, Daejeon (KR); Woong Hahn, Seongnam-si (KR); Jung Hun Lim, Daejeon (KR); Sang Won Lee, Gongju-si (KR); Sung Bae Kim, Seoul (KR); Hyun Tak Kim, Suwon-si (KR)

Correspondence Address: MARSHALL, GERSTEIN & BORUN LLP, 233 S. WACKER DRIVE, SUITE 6300, SEARS TOWER, CHICAGO, IL, 60606, US

(21) Appl. No.: 11/237,100

(22) Filed: Sep. 28, 2005

(30) Foreign Application Priority Data
Apr. 13, 2005 (KR) 10-2005-0030817

(51) Int. Cl. H01L 21/31

(52) U.S. Cl. 438/765

(57) ABSTRACT

Provided are compositions for cleaning a semiconductor device that comprises (a) an inorganic acid in an amount ranging from 10 to 90 wt %, (b) a hydrofluoric acid compound in an amount ranging from 0.0001-1 wt %, (c) an additive in an amount ranging from 0-5 wt %, and (d) residual water to remove residuals of photoresist and metallic etching polymers which are generated in a dry etching process and an ashing process for manufacturing fine patterns of semiconductor device.

### TECHNICAL FIELD

Composition for cleaning a semiconductor device and methods for cleaning a semiconductor device using the same are disclosed. More specifically, compositions for cleaning a semiconductor device and methods for cleaning a semiconductor device using the same are provided to remove residuals of photoresist and metallic etching polymers which are generated in a dry etching process and an ashing process for manufacturing fine patterns of semiconductor device.

### DESCRIPTION OF THE RELATED ART

Due to development of a semiconductor device manufacturing technology and broadening of application field of memory devices, equipments or a technology for manufacturing high-capacity memory devices of high integration has been urgently required. As a result, multilateral studies on a lithography process, a cell structure, new materials which constitute lines and physical property limits of materials which form an insulating film have been made.

The lithography process is essentially applied to a via contact formation process for interconnecting various layers or a pattern formation process. The development of the lithography process of these studies can produce a high-integrated semiconductor device. In the lithography process, a photoresist pattern is formed on a conductive layer or an insulating film formed on a semiconductor substrate, and a region which is not covered by the pattern is removed by an etching process using the photoresist pattern as a mask to obtain a conductive layer or insulating film pattern. Recently, a dry etching process has been used to facilitate control in the etching process for obtaining a sharp pattern in the process for manufacturing semiconductor of high-integrated circuits.

Meanwhile, since the dry etching process is substituted with a wet etching process using a liquid composition of mixed acids, when the dry etching process is performed by using plasma etching gas, ions and radicals included in the plasma etching gas chemically react with the surface of the photoresist, thereby the surface of photoresist film is hardened.

When a semiconductor wafer subjected to ashing treatment after the etching process is heated at a high temperature of over 200° C. to exhaust an asher that remains in the photoresist film, an internal pressure of the photoresist film increases to generate a puffing phenomenon where the surface of the photoresist film is ruptured by remnant of the asher. As a result, it is difficult to remove the residual, dispersed hardened layer, by a conventional subsequent process, thereby degrading production yield of devices. Specifically, metal conductive layers comprising metal such as aluminum, aluminum alloy, copper, copper alloy, titanium, titanium alloy, tantalum, tantalum alloy or tungsten cause residuals of metallic etching polymers, so that it is difficult to remove them by a subsequent strip process with various cleaning solutions.

Various ashing processes have been suggested in order to effectively remove the photoresist hardened layer. Of these processes, a two-step ashing process has been reported (Fujimura, Jpn. J. Appl. Phys. Vol. 28 (1989) 2130-2136). However, these processes are complicated, require large-scale equipments, and produce low yield.

For removing residuals of photoresist film and metallic etching material, the cleaning process that use the cleaning composition obtained by mixing various organic solvents with organic amine compounds including mono-ethanolamine as a necessary element or phenol compound have been developed.

However, since the above cleaning composition does not sufficiently remove residuals which are generated from the chemically hardened photoresist film and metal conductive layer and the cleaning process requires high temperature of over 100° C. and long precipitation time, a stable cleaning process cannot be performed to increase defects of semiconductor devices.

Specifically, when polymer remover compositions comprising hydroxylamine, alkanolamine, anti-corrosive agent and water to effectively remove hardened photoresist polymers are used for the cleaning compositions in semiconductor lines such as DRAMs of over 256M with novel metal film materials as metal lines and novel insulating materials as interlayer insulating films, the photoresist polymers are not completely removed. Therefore, novel compositions to solve the problem have been required.

Accordingly, the present inventors have developed cleaning compositions for semiconductor devices and methods for cleaning semiconductor devices which effectively remove residuals of photoresist and metallic etching polymers without corrosion of lower underlying layers and reduce environmental contamination and high process cost.

### SUMMARY OF THE INVENTION

Disclosed herein are compositions for cleaning a semiconductor device that can remove effectively within a short time residuals of hardened photoresist polymers and metallic etching polymers which are generated in a dry etching process and an ashing process for manufacturing fine patterns of semiconductor device.

Also, disclosed herein are methods for cleaning a semiconductor device using the same.

### BRIEF DESCRIPTION OF THE DRAWINGS

For a more complete understanding of this disclosure, reference should be made to the following detailed description and accompanying drawings wherein:

FIG. 1 is a SEM photograph illustrating Experimental Example 1 where a front view of photoresist pattern is formed on an underlying layer comprising a metal film and then a dry etching process and an ashing process are performed on the photoresist pattern as an etching mask;

FIG. 2 is a SEM photograph illustrating the Example 6 where a cleaning process is performed on the underlying layer pattern of FIG. 1 with a cleaning composition according to an embodiment of the present invention;

FIG. 3 is a SEM photograph illustrating the Comparative Example 1 where a cleaning process is performed on the underlying layer pattern of FIG. 1 with a conventional cleaning composition;

FIG. 4 is a SEM photograph illustrating Experimental Example 2 where a side view of L/S photoresist pattern is formed on an underlying layer for metal line and then a dry etching process and an ashing process are performed on the L/S photoresist pattern as an etching mask;

FIG. 5 is a SEM photograph illustrating the Example 7 where a cleaning process is performed on the L/S metal line pattern of FIG. 4 with a cleaning composition according to an embodiment of the present invention; and

FIG. 6 is a SEM photograph illustrating the Comparative Example 2 where a cleaning process is performed on the L/S metal line pattern of FIG. 4 with a conventional cleaning composition.

### DETAILED DESCRIPTION OF THE EXEMPLARY EMBODIMENTS

A composition for cleaning semiconductor device comprises (a) an inorganic acid in an amount ranging from 10 to 90 wt %, (b) a hydrofluoric acid compound in an amount ranging from 0.0001-1 wt %, (c) an additive in an amount ranging from 0-5 wt %, and (d) residual water.

In the composition, (a) the inorganic acid, which is used to oxidize metallic etching polymers, includes perchloric acid, hydrochloric acid, sulfuric acid, nitric acid, phosphoric acid or acetic acid. Of these acids, the perchloric acid is more effective to remove polymer residuals generated from the etching process. The amount of the inorganic acid included in the cleaning composition according to the embodiment of the present invention ranges from 10 wt % to 90 wt %, preferably from 20 wt % to 40 wt % by the total weight of the composition.

In the composition, (b) hydrofluoric acid compounds uses a hydrofluoric acid or ammonium fluoride having an excellent removing capacity on metal polymers, which is present in an amount ranging from 0.0001 wt % to 1 wt %, preferably from 0.0001 wt % to 0.001 wt % by weight of the composition. If the hydrochloric acid compound is present in the amount of less than 0.0001 wt %, it is difficult to completely remove photoresist and metallic etching polymers. When the hydrochloric acid compound is present in the amount of over 1 wt %, metal lines is corroded heavily.

In the composition, it is preferable to add (c) the additive which is used to prevent corrosion of metal films which is generated by the inorganic acid when the inorganic acid is present in the amount of 40 wt % or more in the composition. As a result, the additive is present in an amount ranging from 0 wt % to 5 wt %, preferably from 0 wt % to 1 wt % by weight of the total weight of the composition. When the inorganic acid is present in the amount of 40 wt % in the composition, the additive is required to be present in the amount ranging from 0.001 wt % to 1 wt % so as to prevent corrosion of metal films. When the additive is present in the amount of over 5 wt % in the composition, the cleaning capacity on photoresist and metallic etching polymers is reduced.

Preferably, the additive is selected from the group consisting of (i) an anti-corrosion agent, (ii) a chelating agent and (iii) a surfactant.

Of the above-described additives, (i) the anti-corrosion agent is selected from the group consisting of an azole compound, a boron compound and an amine compound.

More specifically, the azole compound is one or more selected from the group consisting of triazole compound, benzotriazole compound, imidazole compound, tetrazole compound, thiazole compound, oxazole compound and pyrazole compound. Preferably, the azole compound is one or more selected from triazole compound, benzotriazole compound and imidazole compound.

Here, the triazole compound is one or more selected from triazole, 1H-1,2,3-triazole, 1,2,3-triazole-4,5-dicarboxylic acid, 1,2,4-triazole, 1H-1,2,4-triazole-3-thiol and 3-amino-triazole. The benzotriazole compound is one or more selected from benzotriazole, 1-amino-benzotriazole, 1-hyrdoxy-benzotriazole, 5-methyl-1H-benzotriazole and benzotriazole-5-carboxylic acid. The imidazole compound is selected from the group consisting of imidazole, imidazoline, 1-methyl imidazole, benzimidazole, 1-methyl-benzimidazole, 2-methyl-benzimidazole and 5-methyl-benzimidazole. The tetrazole compound is one or more selected from the group consisting of 1H-tetrazole, 1H-tetrazole-5-acetic acid and 5-amino-tetrazole. The thiazole compound is one or more selected from the group consisting of benzothiazole, 2-methyl-benzothiazole, 2-amino-benzothiazole, 6-amino-benzothiazole and 2-mercapto-benzothiazole. The oxazole compound is one or more selected from the group consisting of isoxazole, benzoxazole, 2-methyl-benzoxazole and 2-mercapto-benzoxazole. The pyrazole compound is preferably pyrazole or 4-pyrazole-carboxylic acid.

The boron compound is one or more selected from the group consisting of boron oxide, boric acid, boron trifluoride, boron trifluoride diethyl etherate, boron trifluoride-ethylamine complex, boron trifluoride-alcohol complex, borane-ammonia complex, borane-buthylamine complex and borane-dimethylamine complex.

The amine compound is one or more selected from the group consisting of methylamine, diethylamine, n-decylamine, morpholine, allylamine, pyridine, quinoline, phenylthiourea, hexamethyleneamine-m-nitrobenzoate, dicyclohexamine nitrite and 1-ethylamino-2-octadecylimidazoline.

Of the above-described additives, (ii) the chelating agent is one or more selected from organic amine chelating agent such as monoethanolamine, diethanolamine, triethanolamine or diethylenetriamine; aminecarboxylic acid complexes such as diethylenetriaminepentacetic acid; and amino acids such as glycine, alanine, valine, leucine, isoleucine, serine, threonine, tyrosine, phenylalanine, tryptophane, aspartic acid, glutamic acid, glutamine, asparagines, lysine, arginine, histidine, hydroxylysine, cysteine, methionine, cystine, proline or hydroxyproline.

Of the above-described additives, (iii) the surfactant, although it is not specifically limited, is one or more selected from the group consisting of. anionic surfactants including ammonium fluoroalkyl sulfone imide, CₙF₂ₙ₊₁CH₂CH₂SO³⁻NH⁴⁺ (here, n is an integer ranging from 1 to 20), CₙF₂ₙ₊₁CH₂CH₂SO₃H (here, n is an integer ranging from 1 to 20) or (CₙF₂ₙ₊₁CH₂CH₂O)ₓPO(ONH⁴⁺)_{y}(OCH₂CH₂OH)_{z} (here, n is an integer ranging from 1 to 20, x+y+z is an integer of 3); nonionic surfactants including CₙF₂ₙ₊₁CH₂CH₂O(OCH₂CH₂OH)ₓH having a molecular weight ranging from 500 to 2000 (here, n is an integer ranging from 1 to 20, x is an integer ranging from 1 to 10), CₙF₂₊₁SO₂N(C₂H₅)(CH₂CH₂)ₓH (n is an integer ranging from 1 to 20, x is an integer ranging from 1 to 10) or fluoroalkyl alkoxylate; and nonionic surfactants which are also chelate compounds including CₙF₂ₙ₊₁CH₂CH₂OCH₂(OH)CH₂CH₂N(CₙF₂ₙ₊₁)₂ (here, n is an integer ranging from 1 to 20) or CₙF₂ₙ₊₁CH₂CH₂OCH₂(OCH₂CH₂)ₙCH₂CH₂N(CₙF₂ₙ₊₁)₂ (here, n is an integer ranging from 1 to 20).

The rest component of the cleaning composition of the present invention is (d) the residual water which is preferably pure water filtered through ion exchange resin, more preferably, ultra fine water having specific resistance of 18MΩ.

Although the conventional cleaning composition resolves polymers by a reduction reaction, it is difficult to remove metallic etching polymers. In order to solve the problem, a cleaning composition including an inorganic acid is used to oxidize residuals of photoresist and metallic etching polymers. Here, an additive is included in the cleaning composition so as to prevent corrosion of metal films which is generated by the inorganic acid.

The cleaning composition includes a hydrofluoric acid compound having an excellent removal capacity to oxide films as well as inorganic acids in order to improve the capacity to remove residuals of photoresist and metallic etching polymers which are generated in the etching process and the ashing process.

Also, disclosed are methods for cleaning a semiconductor device which can remove residuals of photoresist and metallic etching polymers using the cleaning composition.

A disclosed method for cleaning a semiconductor device, comprises:
(a) forming a photoresist pattern on an underlying layer formed on a semiconductor substrate;
(b) etching the underlying layer using the photoresist pattern as an etching mask; and
(c) cleaning the resultant structure with the composition to remove a residual polymer.

The residual polymer is a photoresist polymer or a metallic etching polymer.

In the above-described process, the underlying layer is a metal film or an insulating film. The metal film is formed the combination or deposition of metal selected from the group consisting of aluminum, aluminum alloy, copper, copper alloy, titanium, titanium alloy, tantalum, tantalum alloy and tungsten. Preferably, the metal film is a deposition film of TiN/Al/Ti. The insulating film, although not specifically limited, can be an oxide film or a nitride film.

Meanwhile, the etching process of the step (b) is a dry etching process. After the dry etching process, the method can further comprise an ashing process before a residual of photoresist pattern is removed.

The photoresist pattern is formed by a photolithography process, and an exposure light is selected from group consisting of KrF (248 nm), ArF (193 nm), F₂ (157 nm), EUV (13 nm), E-beam, X-ray and ion-beam. A baking process can be performed before and after the exposure process.

The photoresist pattern can be formed a hole pattern or a line/space pattern.

The cleaning process of the step (c) can be performed using single type or batch type equipment. Although the cleaning condition depend on photoresist materials to be removed, the cleaning process can be performed by spraying the cleaning composition on the substrate or dipping the substrate in the cleaning composition for about 10 seconds to 60 minutes at a chemical temperature ranging from 10° C. to 60° C. to completely remove residuals of photoresist and metallic etching polymers.

In the cleaning process, a process for forming a photoresist pattern using a mask is not performed. Instead, after a dry etching process such as an etch-back process or a CMP (Chemical Mechanical Polishing) process is performed, the cleaning process can be performed with the disclosed cleaning composition.

The cleaning composition can remove effectively within a short time residuals of photoresist polymers and metallic etching polymers which are denatured and hardened by a dry etching process and an ashing process. Specifically, when the combination or deposition film selected from the group consisting of aluminum, aluminum alloy, copper, copper alloy, titanium, titanium alloy, tantalum, tantalum alloy and tungsten is used for a bottom metal film, the residuals of photoresist and metallic etching polymers can be effectively removed.

Meanwhile, the cleaning composition completely removes photoresist polymers, and minimizes corrosion on bottom metal films applied to a high-integrated semiconductor device of over 256M DRAM. Also, an attack phenomenon on HSQ films such as FOX during a process for forming a via hole pattern does not occur.

Also, there is provided a semiconductor device manufactured by using the disclosed cleaning method.

Accordingly, the disclosed cleaning composition is used in a cleaning process for manufacturing a semiconductor device, and also used in a process for manufacturing a LCD (liquid crystal display).

The disclosed cleaning compositions and cleaning methods using the same will be described in more detail by referring to examples below, which are not intended to be limiting. If the following examples contain no additional mention, percentages and mixture ratios are based on the weight of the cleaning composition.

### EXAMPLES 1-5

### Preparation of Compositions for Cleaning a Semiconductor According to the Present Invention

Each component was mixed with the ratio represented in the following Table 1, thereby obtaining compositions for cleaning a semiconductor device of Examples 1-5.

TABLE 1

| | Composition ingredient (weight %) | | | | |
|---|---|---|---|---|---|
| | | (b) | | | |
| | (a) | Hydrofluoric | | | |
| | Inorganic | acid | | | |
| | acid | compound | (c) Additive | | (d) Water |
| Example 1 | Perchloric | Hydrofluoric | Monoethanolamine (0.1) | | Residual |
| | acid (10) | acid (0.5) | | | |
| Example 2 | Perchloric | Hydrofluoric | — | | Residual |
| | acid (20) | acid (1) | | | |
| Example 3 | Perchloric | Hydrofluoric | — | | Residual |
| | acid (40) | acid (0.5) | | | |
| Example 4 | Perchloric | Hydrofluoric | Diethylamine (0.1) | | Residual |
| | acid (50) | acid (1) | | | |
| Example 5 | Perchloric | Ammonium | Diethylamine | Triethanolamine | Residual |
| | acid (60) | fluoride (1) | (0.1) | (0.1) | |

Comparison between the cleaning composition of Examples 1 to 5 and the conventional cleaning composition was performed by the process described in the following experimental examples.

### Experimental Example 1. Cleaning Experiment

(1) Preparation of Sample A

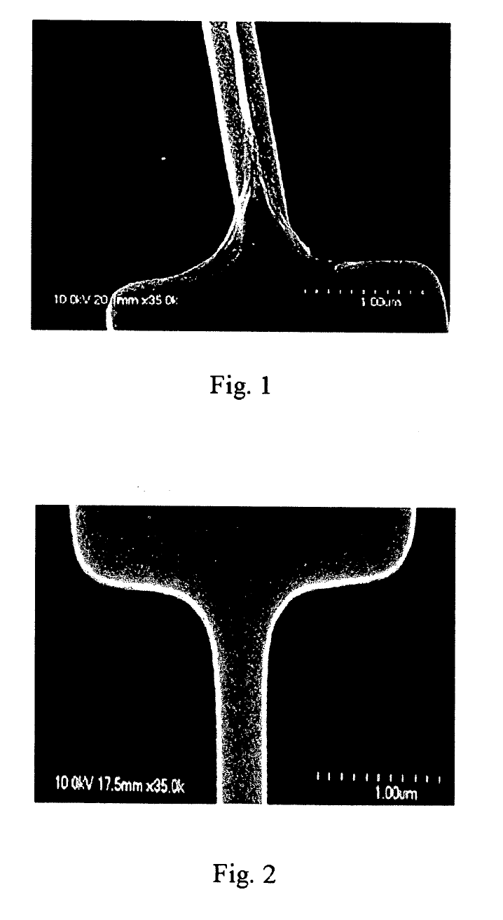

A common positive photoresist composition [product name: DPR-i1000 manufactured by Dongjin Semichem Co., Ltd.] was spin-coated on a 8-inch silicon wafer where a 500 Å TaN film and a 500 Å SiN film were sequentially deposited to have its final thickness of photoresist film of 0.6 μm. Then, the photoresist film was pre-baked at 110° C. for 90 seconds in a hot plate. Next, a predetermined hole-type pattern exposure mask was located over the photoresist film, and the photoresist film is dipped in 2.38 wt % tetramethyl ammonium hydroxide(TMAH) developing solution at 21° C. for 60 seconds to obtain a hole-type photoresist pattern. Then, the sample where the photoresist pattern was formed was hard-baked at 160° C. for 100 seconds. The lower TaN film and the SiN film were etched for 60 seconds by using dry etching equipment (Model: TE8500 produced by Tel Co., Ltd.) which employs CF₄/CHF₃ mixture gas as an etching gas using the photoresist pattern as an etching mask. Thereafter, most of photoresist was removed by the ashing process using O₂ plasma to obtain the sample A. FIG. 1 is a photograph illustrating the top portion of the sample A, which shows that there is a photoresist polymer on the surface.

(2) Cleaning Experiment of Semiconductor Device

### Example 6

The sample A was dipped in the cleaning composition of Example 3 at 50° C. for 60 seconds. After removed from the cleaning composition, the sample A was washed with ultra pure water and dried with nitrogen gas. Then, attachment of the photoresist polymer residuals around sidewalls and on the top surface of the line pattern was checked by SEM (model: S-5000 produced by Hitachi Co., Ltd.) to estimate a removal performance of the photoresist polymer. The test results are shown in Table 2 and FIG. 2.

### Comparative Example 1

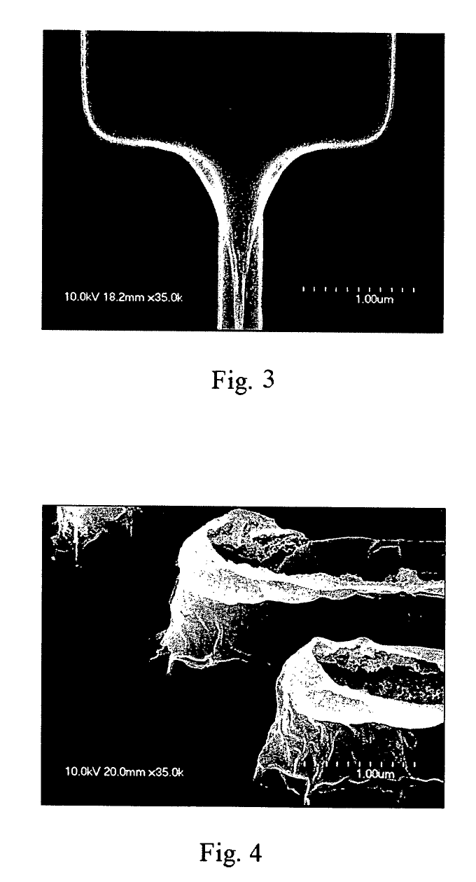

The sample A was dipped in a conventional cleaning composition ACT935 (manufactured by Air Product Co., Ltd.) that comprises hydroxylamine and monoethanolamine as a main component instead of inorganic acids at 75° C. for 30 minutes. Thereafter, the sample A was removed from the cleaning composition, washed with ultra pure water, and dried with nitrogen gas. Then, attachment of the photoresist polymer residuals around sidewalls and on the surface of the line pattern was checked by SEM to estimate a removal performance of the photoresist polymer. The test results are shown in Table 2 and FIG. 3.

TABLE 2

| | Precipitation Time | | |
|---|---|---|---|
| Example 6 | 10 sec.: x | 30 sec.: Δ | 60 sec.: ∘ |
| Comparative Example 1 | 5 min.: x | 10 min.: x | 30 min.: x |

∘: The photoresist residuals are completely removed on the pattern
Δ: The photoresist residuals are mostly removed on the pattern
x: The photoresist residuals are not mostly removed on the pattern

Referring to Table 2, while the photoresist polymer was completely removed by the cleaning composition obtained from Example 3 (see FIG. 2), the photoresist polymer is not removed but still remains in Comparative Example 1 (see FIG. 3).

### Experimental Example 2. Cleaning Experiment

(1) Preparation of Sample B 100 Å TiN film, 8000 Å aluminum film and 400 Å Ti film were sequentially formed on a 8-inch silicon wafer to obtain a deposition film of TiN/Al/Ti. Then, a common positive photoresist composition [product name: DPR-i1000 produced by Dongjin Semichem Co., Ltd.] was spin-coated thereon to have a final film thickness of 1.5 μm. Thereafter, the photoresist film was pre-baked in a hot plate at 110° C. for 90 seconds. Next, a predetermined L/S pattern exposure mask was disposed over the photoresist film, and ultraviolet rays were radiated thereon. Then, the photoresist film was dipped with 2.38 wt % TMAH developing solution at 21° C. for 60 seconds to obtain a L/S photoresist pattern. The sample where the photoresist pattern was formed was hard-baked in the hot plate at 160° C. for 100 seconds. Thereafter, the deposition film of TiN/Al/Ti was etched by using dry etching equipment (Model: DPS+ produced by Applied Material Co.) which employs Cl₂/BCl₃ mixture gas as an etching gas with the photoresist pattern as an etching mask for EPD+ 45 seconds. The photoresist was mostly removed by the ashing process using O₂ plasma to obtain the sample B. FIG. 4 is a photograph illustrating a pattern profile of the sample B, which shows that there are the photoresist polymer and a large amount of metallic etching polymer on the top surface and sidewalls of the metal line.

(2) Cleaning experiment of semiconductor device

### Example 7

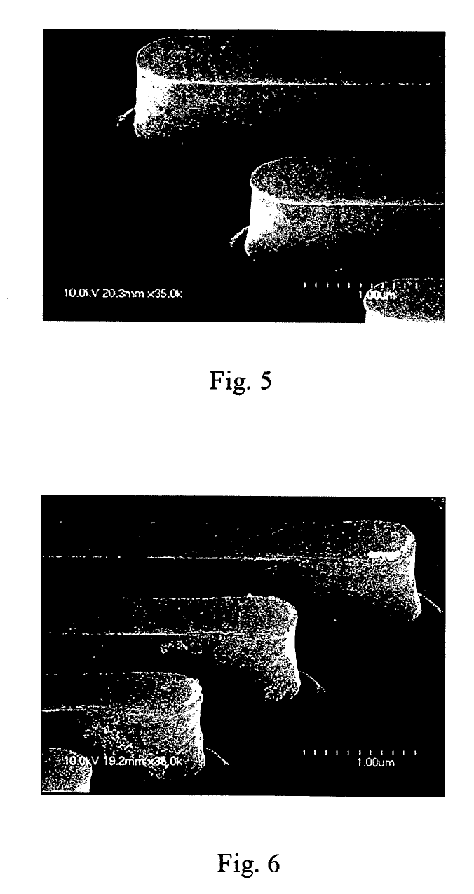

The sample B was dipped in the cleaning composition of Example 3 at 50° C. for 60 seconds. The sample B was removed from the cleaning solution, washed with ultra fine water, and dried with nitrogen gas. Then, attachment of the photoresist polymer residuals around sidewalls and on the surface of the line pattern was checked by SEM to estimate a removal performance of the photoresist polymer. The test results are shown in Table 3 and FIG. 5.

### Comparative Example 2

The same procedure of Example 7 was repeated except in that the sample B was dipped in the conventional cleaning composition ACT935 instead of the cleaning solution obtained from Example 3 at 75° C. for 30 minutes to estimate a polymer removal performance. The test results are shown in Table 3 and FIG. 6.

TABLE 3

| | Precipitation Time | | |
|---|---|---|---|
| Example 7 | 10 sec.: x | 30 sec.: Δ | 60 sec.: ∘ |
| Comparative Example 2 | 5 min.: x | 10 min.: x | 30 min.: x |

∘: The photoresist residuals are completely removed on the pattern
Δ: The photoresist residuals are mostly removed on the pattern
x: The photoresist residuals are not mostly removed on the pattern

Referring to Table 3, while the photoresist polymer was completely removed by the cleaning composition obtained from Example 3 (see FIG. 5), the photoresist polymer is not removed but still remains in Comparative Example 2 (see FIG. 6).

As described above, the disclosed composition for cleaning a semiconductor device easily removes residuals of photoresist and metallic etching polymers which are denatured and hardened by a dry etching process and an ashing process during a process for forming a fine pattern of a semiconductor device within a short time, and also minimizes corrosion of lower metal lines in a cleaning process to prevent defects of the device and reduce the cleaning time of the semiconductor device, thereby improving productivity of the semiconductor manufacturing process.

What is claimed is:

1. A composition for cleaning a semiconductor device comprising:
(a) an inorganic acid in an amount ranging from 10 to 90 wt %, (b) a hydrofluoric acid compound in an amount ranging from 0.0001-1 wt %, (c) an additive in an amount ranging from 0-5 wt %, and (d) residual water.

2. The composition according to claim 1, wherein the composition for cleaning a semiconductor device comprises (a) an inorganic acid in an amount ranging from 20 to 40 wt %, (b) a hydrofluoric acid compound in an amount ranging from 0.0001-0.001 wt %, (c) an additive in an amount ranging from 0-1 wt %, and (d) residual water.

3. The composition according to claim 1, wherein (a) the inorganic acid is selected from the group consisting of perchloric acid, hydrochloric acid, sulfiric acid, nitric acid, phosphoric acid or acetic acid.

4. The composition according to claim 1, wherein (b) the hydrochloric acid compound is hydrofluoric acid or ammonium fluoride; (c) the additive is selected from the group consisting of (i) an anti-corrosion agent, (ii) a chelating agent and (iii) a surfactant; and (d) the water is pure water.

5. A method for cleaning a semiconductor device, the method comprising the steps of:
(a) forming a photoresist pattern on an underlying layer formed on a semiconductor substrate;
(b) etching the underlying layer using the photoresist pattern as an etching mask; and
(c) cleaning the resultant structure with the composition of claim 1 to remove a residual polymer.

6. The method according to claim 5, wherein the underlying layer is an insulating film or a metal film.

7. The method according to claim 6, wherein the metal film comprise metal selected from the group consisting of aluminum, aluminum alloy, copper, copper alloy, titanium, titanium alloy, tantalum, tantalum alloy, tungsten and combinations thereof.

8. The method according to claim 5, wherein the residual polymer is a photoresist polymer or a metallic etching polymer.

9. The method according to claim 5, wherein the etching of the step (b) is a dry etching process.

10. The method according to claim 5, further comprising performing an ashing process after the etching process of the step (b).

11. The method according to claim 5, wherein the photoresist pattern is a hole pattern or a L/S pattern.

12. The method according to claim 5, wherein the cleaning process of the step (c) is performed by dipping the substrate in the cleaning composition at a temperature ranging from 10° C. to 60° C. for 10 seconds to 60 minutes.
